(19) United States
(12) Patent Application Publication
(10) Pub. No.: US 2009/0201653 A1
(43) Pub. Date: Aug. 13, 2009

(54) Fixing device

(75) Inventors: Gen Yin, Shanhai City (CN); Fanlan Qu, Shanhai City (CN); Tsai-Kuei Cheng, Taipei City (TW)

Correspondence Address: Edwards Angell Palmer & Dodge LLP, P.O.Box 55874, Boston, MA, 02205, US

(73) Assignee: Inventec Corporation, Taipei City (TW)

(21) Appl. No.: 12/069,893

(22) Filed: Feb. 13, 2008

(51) Int. Cl. H05K 5/00; H05K 5/02

(52) U.S. Cl. 361/752

(57) ABSTRACT

A fixing device is provided for disposing an interface card in a casing of an electronic device, wherein the casing of electronic device includes lateral walls, a peripheral component bracket fixed to the casing. The fixing device includes a rotating bracket and an interface bracket, wherein the rotating bracket is fixed to the lateral wall, and connecting portions, and a first limiting portion. The interface bracket includes rotating portions pivotally connected to the connecting portions, a second limiting portion corresponding to the first limiting portion, and a coupling portion coupled to the peripheral component bracket. The interface bracket is rotated relatively to the casing of the electronic device, and the movement of the interface bracket is limited to the vertical movement by the rotating bracket.

### BACKGROUND OF THE INVENTION

1. Field of the Invention

This invention generally relates to a fixing technique, and more particularly, to a fixing device for an interface card to be disposed in an electronic device.

2. Description of Related Art

With continuous development and advancing improvement in the electronic industry, electronic devices such as computers and servers are advanced day by day. In order to answer demands of multi-applications, designs of electronic devices are also getting more precision. Therefore, how to effectively make use of interior space of a case of electronic device and achieve its best economical efficiency has become a focused issue in the industry, and accordingly, the way for fixing various components to an electronic device is getting dramatically significant.

For example, a motherboard, CD-ROM drive, floppy disk unit, hard disk, and other components are disposed in a server. In order to expand performance with more functions, a plurality of peripheral component interconnect (PCI) interface cards or other interface cards are allocated on the motherboard. In order to dispose a PCI interface card in the motherboard, a corresponding PCI slot is formed in the casing of the electronic device for fixing one side of the PCI interface card, and also an interface bracket is installed for containing the other side of the PCI interface card, thereby expanding performance of electronic device with more functions.

Please refer to FIG. 1, which is a diagram showing a PCI interface bracket 10 installed in the casing of the electronic device 12. As shown in the FIG., the PCI interface bracket 10 is fixed to one lateral wall of the casing of electronic device 12 via screws, and is disposed between a peripheral component bracket 14 such as a hard disk bracket and the lateral wall of the casing of the electronic device 12. Since the wires, such as signal wires or power source wires, from hard disks in the peripheral component bracket 14 have to been pulled out, and the space is limited, so that only three PCI interface cards can be accommodated therein.

As broadening applications of server; however, it is incapable of satisfying the increasing demands of expanding functions of servers that only three PCI interface cards or other interface cards can be installed in the prior art.

In view of the above, as shown in FIG. 2, a partition 24 is provided to increase the number of the installed PCI interface cards. The partition 24 is transversely installed in a casing of the electronic device 22. The partition 24 is fixed to the case of electronic device 22, and a plurality of thumb screws 26 are applied to fix a PCI interface bracket 20 to the partition 24, thereby allowing more PCI interface cards for instance, 7 PCI interface cards as shown in FIG. 2 to be installed therein. Also, as shown in FIG. 2, four thumb screws 26 are applied to fix the interface bracket to the casing, and there is no need of tools for assembly/disassembly.

However, the partition 24 must be additionally provided in the casing of the electronic device, and also electrical connections of other components, such as hard disks and power source, must be taken into consideration. In addition, there must be a space between the partition 24 and other components, and a circuit board is disposed in that space for the electrical connections, thereby occupying the space in the casing of the electronic device, and shortening the distance between the PCI interface bracket 20 and the casing of electronic device 22. Therefore, longer PCI interface cards cannot be installed in the casing. For installing longer PCI interface cards, the length of the casing of electronic device must be increased, so as to increase production cost in consequence will be dramatically increased. In addition, although the aforesaid prior art provides a convenient means of assembly/disassembly without need of tool, thumb screws are expensive, i.e. applying four thumb screws for each electronic device indeed increases production cost relatively. Furthermore, in the prior art, wiring space can only be revealed after the PCI interface bracket 20 is completely taken apart, thereby consuming more time and work.

Hence, it is a highly urgent issue in the industry to provide a fixing technique, which can effectively solve the drawbacks of the prior art as mentioned above, thereby providing a simple structure to enhance efficiency of utilizing space in casing of electronic device, and providing convenient application of assembling/disassembling the interface bracket.

### SUMMARY OF THE INVENTION

In view of the disadvantages of the prior art mentioned above, it is a primary objective of the present invention to provide a fixing device for enhancing efficiency of utilizing space in the casing of an electronic device.

It is another objective of the present invention to provide a fixing device for facilitating assembly/disassembly.

It is a further objective of the present invention to provide a fixing device for enhancing flexibility of assembly/disassembly.

It is still another objective of the present invention to provide a fixing device for lowering production cost.

To achieve the aforementioned and other objectives, a fixing device is provided in the present invention. The fixing device is provided for disposing an interface card to a casing of an electronic device, wherein the casing of electronic device has lateral walls, and peripheral component bracket fixed in the casing of the electronic device.

The fixing device comprises a rotating bracket fixed to the lateral wall of the casing and has connecting portions and a first limiting portion; and an interface bracket pivotally disposed on one side of the rotating bracket, and having rotating portions pivotally connected to the connecting portions, a second limiting portion corresponding to the first portion, and a coupling portion coupled to the peripheral component bracket.

In the aforesaid fixing device, a securing element is disposed and passes through the coupling portion, wherein the securing element can be a screw or a thumb screw. The connecting portion is a hole and the first limiting portion is an L-shaped flange. The rotating portion includes a flange connected to the interface bracket, and an insertion portion extending form the flange. The second limiting portion is disposed on one side of the flange, wherein the second limiting portion is a gap, and the coupling portion is one of a threaded hole and a through hole.

In summary, the fixing device of the present invention provides a rotating bracket and an interface bracket that are pivotally connected to each other, the rotating bracket is fixed to the lateral wall of the casing of the electronic device, and the interface bracket is capable of rotating relatively to the casing of the electronic device and fixed to peripheral component bracket in the casing of the electronic device. Compared with the prior art using a partition for fixing the interface bracket, the present invention indeed enhances efficiency of utilizing space in the casing of the electronic device and saves cost. In addition, the fixing device of the present invention is capable of rotating freely, so as to not only increase efficiency of utilizing space in a casing of an electronic device, but also provide flexibility of wiring and assembly, and further simplify assembly structure and facilitate assembly/disassembly.

### BRIEF DESCRIPTION OF DRAWINGS

The present invention can be more fully understood in light of the following detailed description of the preferred embodiments, with reference to the accompanying drawings, wherein:

FIG. 1 is a diagram showing an interface bracket installed in a casing of an electronic device according to the prior art;

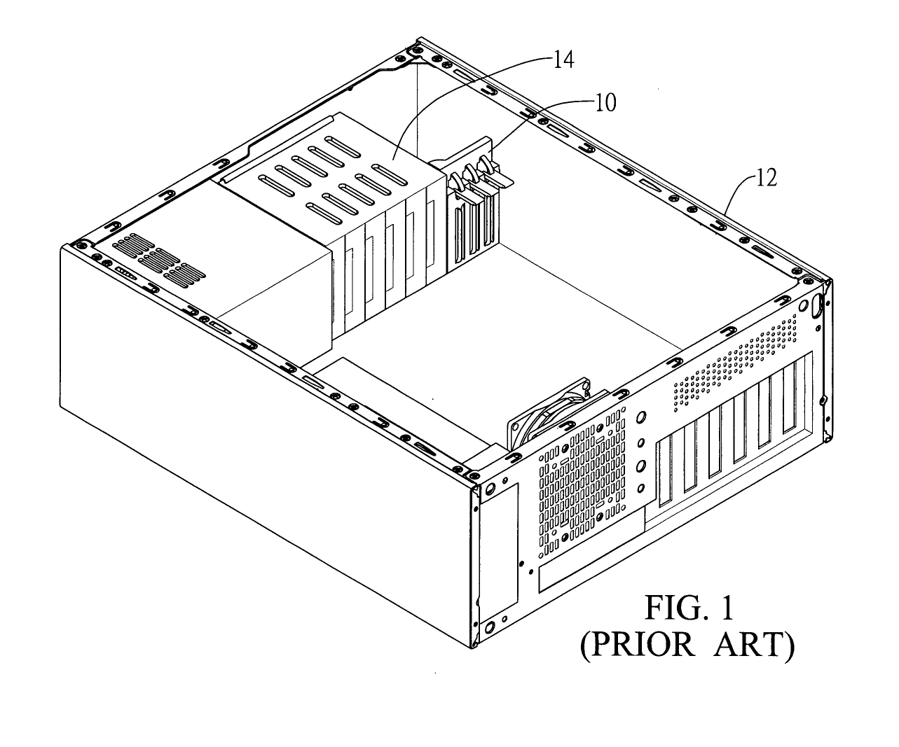

FIG. 2 is a diagram showing an interface bracket installed in a casing of an electronic device according to the prior art; and

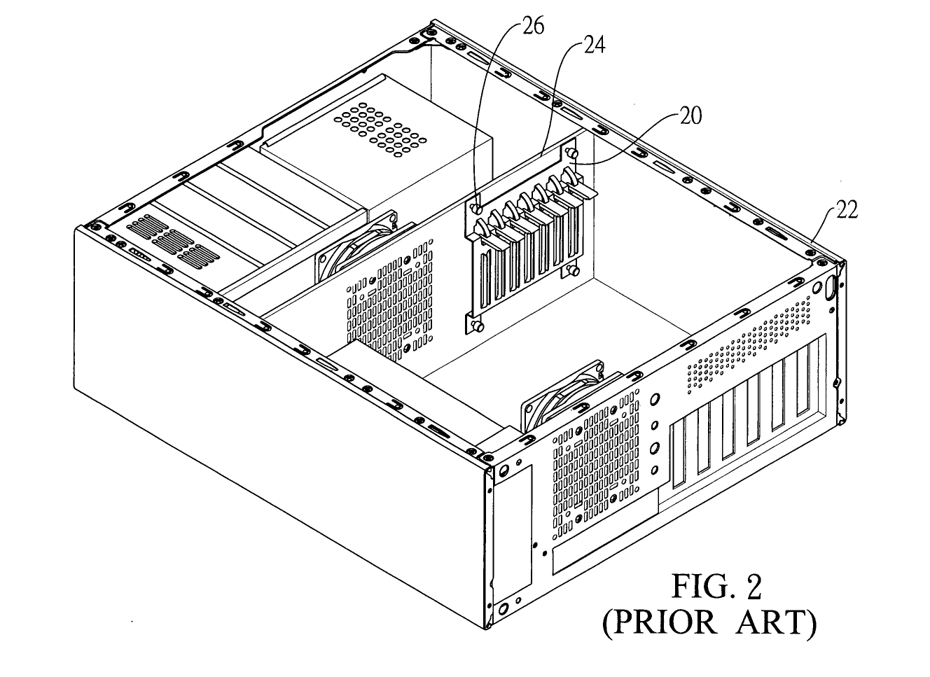

FIG. 3a is a diagram showing the fixing device fixed to the casing of electronic device according to the present invention;

FIG. 3b is a diagram showing an amplification of a portion of the view shown in FIG. 3a;

FIG. 3c is a diagram showing the rotation of the interface bracket in the fixing device according to the present invention; and

FIG. 3d is a diagram showing the interface card fixed in the casing of the electronic device via the fixing device according to the present invention.

### DETAILED DESCRIPTION OF PREFERRED EMBODIMENTS

The following illustrative embodiments are provided to illustrate the disclosure of the present invention, and these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

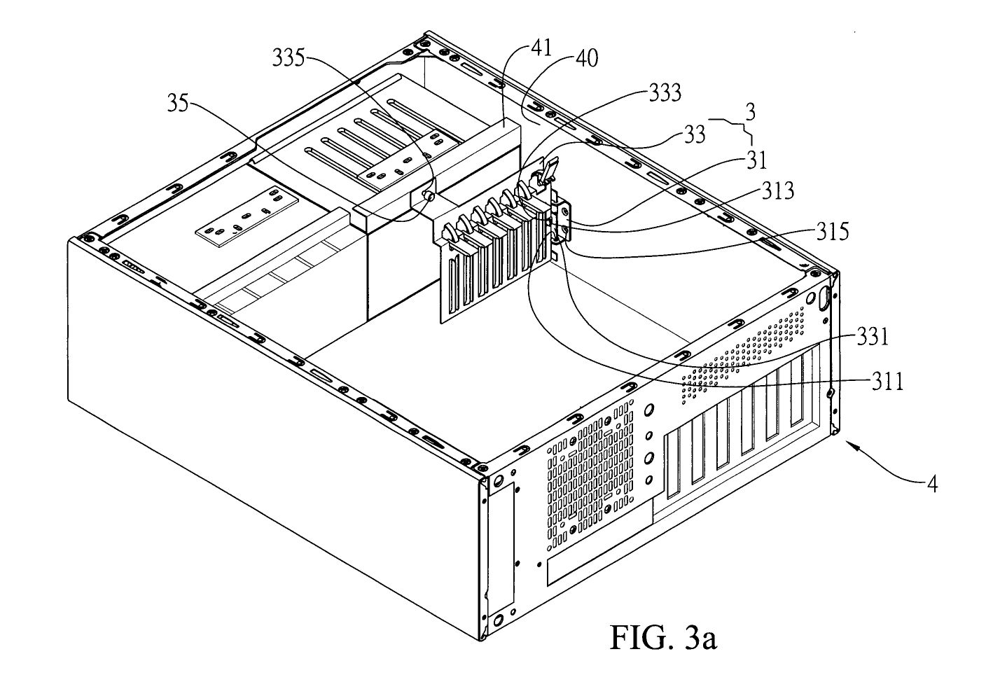

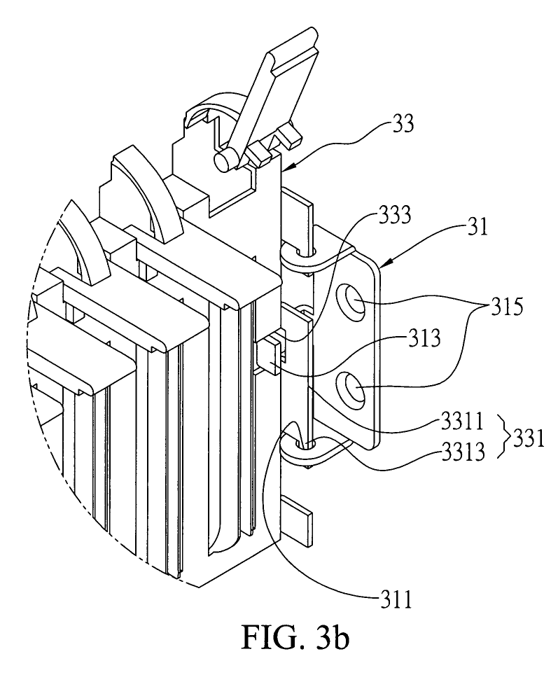

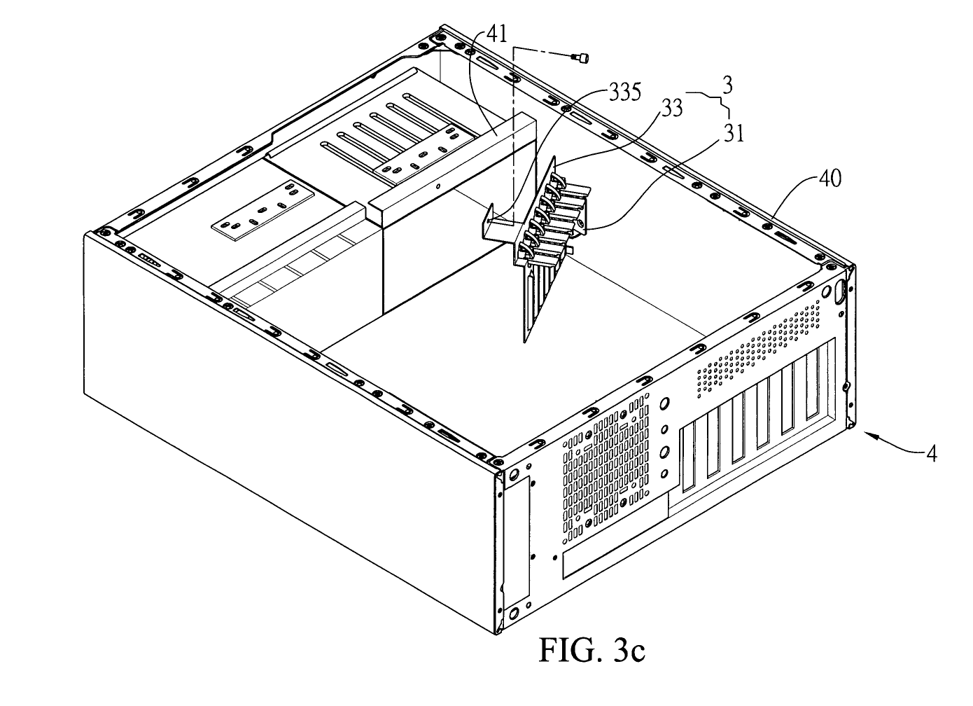

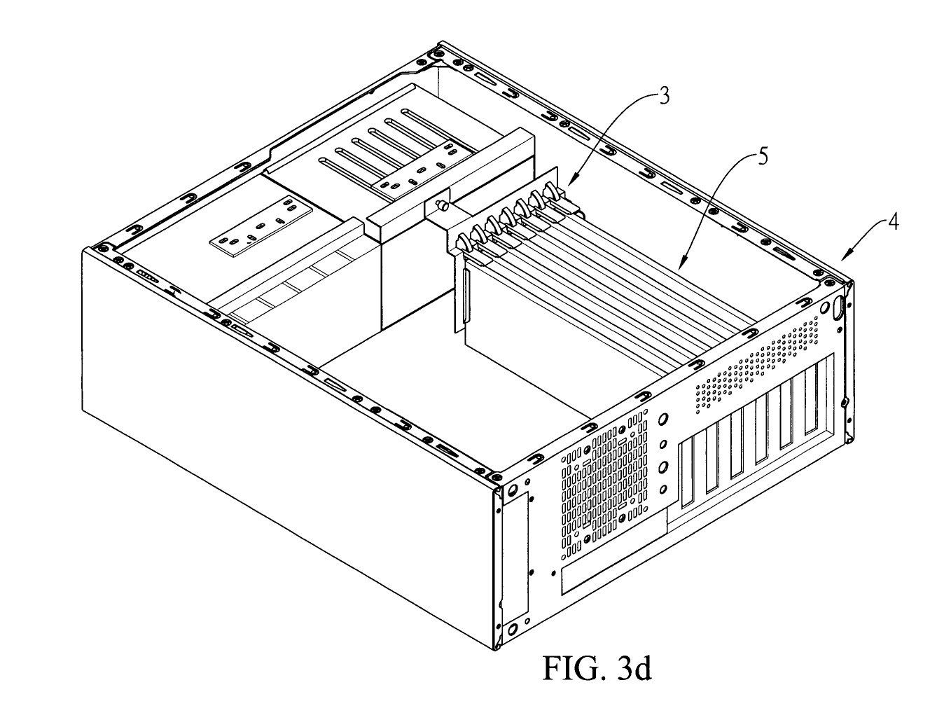

FIGS. 3a through 3d are diagrams showing the fixing device according to the present invention. The fixing device of the present invention is provided for fixing interface cards to a casing of an electronic device. It should be noted that in the present invention, the interface cards are used for expanding functions of electronic device, and the electronic device can be personal computer, server, or any other electronic device that has functions to be expanded. Also, it should be noted that structures and purposes of the electronic device and interface cards are well understood by those in the art, and are not features of the present invention, and thus in order to make features of the present invention easier to be comprehended, all diagrams are simplified to illustrate related featured structures only. Therefore, structures of components illustrated in the drawings are to disclose the features and functions of the present invention but do not limit the scope of the present invention.

Please refer to FIGS. 3a and 3b, wherein FIG. 3a is a diagram showing the structure of the fixing device applied to a casing of an electronic device according to the present invention. FIG. 3b is a diagram showing the amplification of a portion of view shown in FIG. 3a.

As shown in FIG. 3a, the casing 4 of the electronic device has lateral walls 40, and a peripheral component bracket 41 is fixed in the casing 4 of the electronic device. The peripheral component bracket 41 is, for instance a hard disk bracket, but not restricted to as stated herein. The fixing device 3 includes a rotating bracket 31, and an interface bracket 33 pivotally connected to the rotating bracket 31.

The rotating bracket 31 is fixed to the lateral wall 40, and has a connecting portion 311 and a first limiting portion 313. In the present embodiment, by bending upper and low ends of the rotating bracket, a pair of flanges are formed on the upper and lower ends of the rotating bracket respectively, and the connecting portions 311 are respectively formed on the flanges. The connecting portions 311 can be holes, for instance round holes, and are perpendicular to the lateral wall 40. The first limiting portion 313 is disposed between the connecting portions 311, and has a length longer than the length of each upper/low flange of the rotating bracket 31. In the present embodiment, the first limiting portion can be a flange, for instance an L-shaped flange, but not limited to as stated herein. The rotating bracket 31 can further include coupling holes 315, which can be either threaded holes or through holes. Therefore, the rotating bracket 31 can be fixed to the lateral wall 40 via securing elements, such as screws or rivets.

The interface bracket 33 includes rotating portions 331 pivotally connected to the connecting portions 311, a second limiting portion 333 corresponding to the first limiting portion 313; and a coupling portion 335 coupled to the peripheral component bracket 41. As shown in FIG. 3b, the rotating portion 331 further includes a flange 3311 connected to the interface bracket 33, and an insertion portion 3313 extending from the flange 3311, wherein the second limiting portion 333 is disposed on one side of the flange 3311. In the present embodiment, the second limiting portion 333 is a gap, for instance a rectangular gap. Further, the second limiting portion 333 can be any equivalent structure capable of restricting the first limiting portion 313 to move vertically. The coupling portion 335 is a threaded hole, and in other embodiments, the coupling portion 335 can also be any equivalent structure, such as through hole or others, which provides a means of coupling with the peripheral component bracket 41.

Certainly, the interface bracket 33 can further include slots for receiving sides of interface cards and wedging portions for containing tops of the interface cards. Since slots and wedging portions are well known to those in the art and are not features of the present invention, there is no need of detailed description herein.

The fixing device 3 can further comprises a securing element 35 passing through the coupling portion 335, wherein the securing element 35 can be a thumb screw. The thumb screw is provided as an example of the securing element 35 to facilitate the assembly/disassembly without need of a tool; however, in other embodiments, the securing element can also be a screw or other equivalent structure that is capable of fixing the interface bracket 33 to the peripheral component bracket 41.

During the assembly of the fixing device 3 and the casing 4 of the electronic device in the present invention, the rotating bracket 31 is fixed to the lateral wall 40, then the rotating portion 331 of the interface bracket 33 is targeted at the connecting portion 311 of the rotating bracket 31, the insertion portion 3313 is inserted into the connecting portion 311 and then pushed down, and the coupling portion 335 of the interface bracket 33 is coupled to the peripheral component bracket 41. Thus, a completed assembly is shown in FIG. 3a. Referring to FIGS. 3a through 3c, since the first limiting portion 313 and the second limiting portion 333 are intersecting to each other, so that the movement of the interface bracket 33 is restricted to the vertical movement. As shown in FIG. 3d, when the fixing device 3 of the present invention is completely installed, interface cards 5 can be installed in the casing 4 of the electronic device. The interface cards can be, for instance, PCI interface cards or other interface cards.

In addition, since the rotating portions 331 are pivotally connected to the connecting portions 311, when the coupling portion 335 is disassembled from the peripheral component bracket 41, the interface bracket 33 is capable of rotating. Therefore, detachment of the interface bracket 33 can be done by rotating the interface bracket 33 until the first limiting portion 313 and the second limiting portion 333 are released from the intersection of each other, and then the interface bracket 33 can be easily detached from the rotating bracket 31.

Furthermore, in the fixing device 3 of the present invention, the interface bracket 33 is provided with capability of rotation, and therefore before completing wiring in the casing of the electronic device, the only process to be done is to disassemble the coupling portion 335 from the peripheral component bracket 41 and then correspondingly rotate the interface bracket 33. After that, wiring can be performed between components such as hard disks and motherboard and others, thereby overcoming drawbacks, i.e. the interface bracket has to be detached completely to provide space for wiring in the prior art. Accordingly, the present invention provides flexibility of assembly/disassembly.

In view of the above, in the fixing device of the present invention, a rotating bracket is disposed to allow interface bracket to rotate laterally, limiting portions are disposed between the rotating bracket and the interface bracket, thereby restricting the movement of the interface bracket to vertical movement, and one side of the interface bracket, which is not pivotally connected to the rotating bracket, is fixed. Therefore, there is no need of an additional partition as in the prior art for fixing the interface bracket, and the present invention is applicable to existing casing of electronic devices. Hence, the present invention enhances efficiency of utilizing space in a casing of an electronic device and saves cost.

In addition, the fixing device of the present invention has the capability of rotation, so as to enhance efficiency of utilizing space in the casing of electronic device, facilitate wiring inside the casing of electronic device, and simplify assembly structure. Compared with the prior art, in which screws must be applied in a time- and work-consuming process, the simplified assemble structure of the present invention provides an easier means of assembly/disassembly. Furthermore, there is no need of four thumb screws as in the prior art, so that the present invention saves cost.

The foregoing descriptions of the detailed embodiments are only illustrated to disclose the features and functions of the present invention and do not limit the scope of the present invention. It should be understood to those in the art that all modifications and variations according to the spirit and principle in the disclosure of the present invention should fall within the scope of the appended claims.

What is claimed is:

1. A fixing device for disposing an interface card in a casing of an electronic device, wherein the casing of the electronic device comprises a lateral wall and a peripheral component bracket fixed therein, the fixing device comprises:
a rotating bracket fixed to the lateral wall and having a connecting portion and a first limiting portion; and
an interface bracket pivotally disposed on one side of the rotating bracket, and has a rotating portion pivotally connected to the connecting portion, a second limiting portion corresponding to the first limiting portion, and a coupling portion coupled to the peripheral component bracket.

2. The fixing device of claim 1, further comprising a securing element passing through the coupling portion.

3. The fixing device of claim 2, wherein the securing element is a screw.

4. The fixing device of claim 2, wherein the securing element is a thumb screw.

5. The fixing device of claim 1, wherein the connecting portion is a hole.

6. The fixing device of claim 1, wherein the first limiting portion is an L-shaped flange.

7. The fixing device of claim 1, wherein the rotating portion comprises a flange connected to the interface bracket, and an insertion portion extending from the flange.

8. The fixing device of claim 7, wherein the second limiting portion is disposed on one side of the flange.

9. The fixing device of claim 1, wherein the second limiting portion is a gap.

10. The fixing device of claim 1, wherein the coupling portion is one of a threaded hole and a through hole.
